(19) United States
(12) Patent Application Publication
(10) Pub. No.: US 2013/0271111 A1
(43) Pub. Date: Oct. 17, 2013

(54) SMART AC PANEL

(71) Applicant: Tejesh C Makanawala, Mountain View, CA (US)

(72) Inventor: Tejesh C Makanawala, Mountain View, CA (US)

(21) Appl. No.: 13/808,253

(22) PCT Filed: Aug. 24, 2011
(86) PCT No.: PCT/IB11/02922

§ 371 Date: Jan. 4, 2013

Related U.S. Application Data
(60) Provisional application No. 61/376,269, filed on Aug. 24, 2010.

(51) Int. Cl. G01R 21/06

(52) U.S. Cl. CPC G01R 21/06
USPC 324/76.11

(57) ABSTRACT

Smart AC Panel replaces the existing AC Panel in a home. It not only includes existing AC Panel function such as bus bar and circuit breakers, but also current sensor, voltage sensing circuitry and relay devices to help control and monitor power associated with each branch circuit. The current sensor, voltage sensing circuitry interfaces to an embedded controller. Various embedded controllers are connected through CAN serial communication to a supervisory embedded controller which in turn has internet connectivity.

### RELATED APPLICATIONS

The present application is a continuation-in-part application of United States provisional patent application, Ser. No. 61/376,269, filed Aug. 24, 2010, for SMART AC PANEL, by TEJESH MAKANAWALA, included by reference herein and for which benefit of the priority date is hereby claimed.

### FIELD OF THE INVENTION

The present invention relates to AC panels in homes and, more particularly, to adding smartness and internet connectivity to these AC panels.

### BACKGROUND OF THE INVENTION

As the world heads towards reduced energy consumption and lower energy costs, green technology products for homes are being constantly released to the market. In order to better understand what products need replacement, one needs to better understand what energy it is consuming. It would also be useful to experiment with reducing energy consumption of existing devices by programmatically enabling and disabling the device.

The most common solutions for this problem is distributed control systems for the home, also called home automation systems. It comprises of a central main controller and various wirelessly or powerline controlled AC modules. The controllers are installed in an accessible area of the home and the AC modules are connected to each outlet of the home.

Due to the added cost of each module, generally many of the outlets are skipped. The combined module and installation cost makes the solution expensive and not practical.

It is therefore an object of the invention to control and monitor power on each circuit in the home.

It is another object of the invention to monitor power generated by solar panel installation in the home.

It is another object of the invention to schedule charging time for electric car to optimize charging cost.

It is another object of the invention to control every outlet powered device in the home.

### SUMMARY OF THE INVENTION

Smart AC Panel replaces the existing AC Panel in a home. It not only includes existing AC Panel function such as bus bar and circuit breakers, but also current sensor, voltage sensing circuitry and relay devices to help control and monitor power associated with each branch circuit. The current sensor, voltage sensing circuitry interfaces to an embedded controller. Various embedded controllers are connected through CAN serial communication to a supervisory embedded controller which in turn has internet connectivity.

### BRIEF DESCRIPTION OF THE DRAWINGS

A complete understanding of the present invention may be obtained by reference to the accompanying drawings, when considered in conjunction with the subsequent, detailed description, in which:

FIG. 1 is a schematic view of a smart ac panel internally; and

FIG. 2 is a schematic view of a smart ac panel showing critical components.

For purposes of clarity and brevity, like elements and components will bear the same designations and numbering throughout the Figures.

### DESCRIPTION OF THE PREFERRED EMBODIMENT

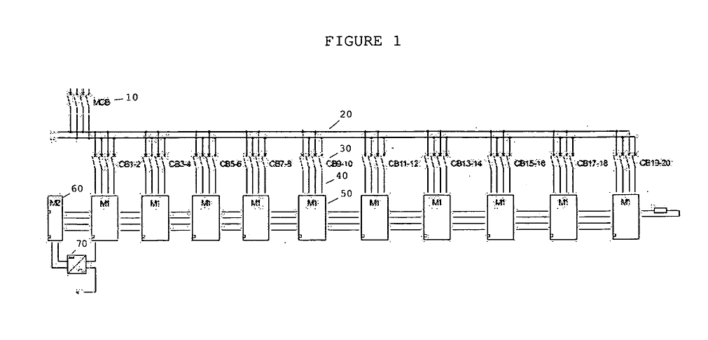

FIG. 1 is a schematic view of a Smart AC panel internally. It shows the Main Circuit Breaker (MCB) 10 on top connected to the Busbar 20. Branch Circuit Breaker (CBx) 30 is shown as 4 breakers, though in general they are 1 or 2. L1 and L2 go to first and second circuit of a 2 pole breaker. Wires 40 in a standard AC panel leave the panel, but in a Smart AC Panel, they connect to the M1PCB 50. The external wires 40 are connected via ConnectionPoint 100. The M1PCB 50 and M2PCB 60 are powered with +5 VDC 94 from the DCpowersupply 70. Common GND 92 is used.

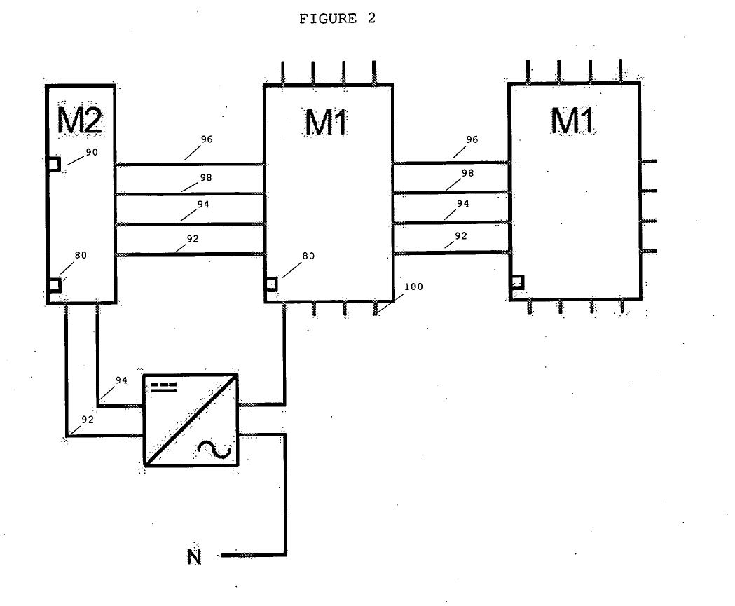

FIG. 2 is a schematic view of a Smart AC panel focusses on the interfaces between M1PCB 50 and M2PCB 60, and how they are integrated with rest of the system. M1PCB 50 has CAN-High 96 and CAN-Low 98 interface to communicate with M2PCB 60. Both M1PCB 50 and M2PCB 60 have a Debugport 80 for software debugging. Ethernetport 90 in included in the M2PCB 60 to provide internet/web connectivity.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. A Smart ac panel for monitoring and controlling power usage in every circuit in homes by displacing standard ac panels, comprising:
means for measuring voltage and current, controlling power to load (or internal source, eg: solar panel), calculating power consumed or generated and providing means to communicate to external device via can serial interface; and
means for providing a web/internet interface for smart ac panel.
